(19) United States
(12) Patent Application Publication
(10) Pub. No.: US 2025/0287770 A1
(43) Pub. Date: Sep. 11, 2025

(54) SOLAR CELLS AND DEVICES USING TRIVALENT METAL DOPING

(71) Applicant: UNIVERSITY OF SEOUL INDUSTRY COOPERATION FOUNDATION, Seoul (KR)

(72) Inventors: Hyeok KIM, Seoul (KR); Swarup BISWAS, Seoul (KR)

(21) Appl. No.: 19/072,286

(22) Filed: Mar. 6, 2025

(30) Foreign Application Priority Data
Mar. 6, 2024 (KR) 10-2024-0032205

(51) Int. Cl. H10K 30/85; H10K 30/50; H10K 30/86; H10K 71/30; H10K 85/20

(52) U.S. Cl. CPC H10K 30/85; H10K 30/50; H10K 30/86; H10K 71/30; H10K 85/215

(57) ABSTRACT

Provided is a solar cell utilizing trivalent metal doping and a method for manufacturing an inverted-structure organic solar cell (OSC), the method including: preparing a TiO₂ precursor solution using titanium (IV) butoxide (Ti(OCH₂CH₂CH₂CH₂CH₃)₄); dissolving and stirring the TiO₂ precursor solution in a mixture of 2-methoxyethanol (CH₃OCH₂CH₂OH) and acetylacetone (CH₃COCH₂COCH₃); dissolving Ga(NO₃)₃·xH₂O or In(NO₃)₃·xH₂O in the TiO₂ precursor solution to prepare a doped TiO₂ precursor solution. According to the method, it is possible to manufacture an inverted-structure OSC with improved power conversion efficiency (PCE) compared to conventional inverted-structure OSCs.

### CROSS-REFERENCE TO RELATED APPLICATION

This application claims priority to and the benefit of Korean Patent Application No. 10-2024-0032205, filed on Mar. 6, 2024, the disclosure of which is incorporated herein by reference in its entirety.

### BACKGROUND

### 1. Field of the Invention

The present invention relates to a solar cell using trivalent metal doping. More specifically, the invention pertains to an inverted-structure organic solar cell with improved power conversion efficiency (PCE) by considering the impact assessment of trivalent metal doping on the performance of titanium dioxide (TiO₂) as an electron transport layer.

### 2. Discussion of Related Art

Organic solar cells (OSCs) have received substantial interest in recent years from both the academic and electronic industry sectors because to their high potential for use as low cost, flexible, lightweight, transparent, low dimension, and efficient light energy harvesters. Recently, the maximum power conversion efficiency (PCE) value of an OSC reached more than 18% as a result of tremendous efforts made over the past several years in areas like the fabrication of different semiconductors for using as donor acceptor, the synthesis of different semiconducting interlayers (hole extraction layer (HEL), electron transport layer (ETL), implementation of bandgap engineering, and device structure optimization. The basic OSC structure can be classified into two different types, namely conventional and inverted structures. There are several challenges associated with the conventional structured OSCs, including low environmental stability due to the etching effect of interlayer, easy oxidation of top electrode, and low photo stability. Inverted structures of OSCs have recently been devised to solve the issues associated with conventional structured OSCs due to greater device stability and manufacturing compatibility. Alongside these advantages, the inverted structured OSCs have a serious issue of a low PCE value, which is primarily due to poor electron transport ability of the n-type semiconductors that are utilized as the ELT in this device. Several inorganic oxide materials, including as tin oxide (SnO₂), zinc oxide (ZnO), and titanium oxide (TiO₂) have been used as ETLs for inverted OSCs to increase electron collection at the indium tin oxide (ITO) cathode. Among these, TiO₂ is the most commonly adopted ETL for photo- and air-stable OSCs owing to its chemical stability and non-toxicity; however, it exhibits a poor PCE value due to the considerably low conductivity of undoped TiO₂, which is a crucial issue that needs to be addressed. As a result, multiple research groups have investigated the utilization of different metal doped ETLs to increase the PCE of inverted OSCs. Metal doping is a viable strategy for changing grain size, conductivity, and orientation, and it has the ability to greatly affect the optoelectronic properties of ETLs. In this regard, the selection of the doping metal is very important because the atomic size varies for different metals; during doping, the lattice mismatch arises because of the difference in atomic size of Ti, and the doping metal may affect the charge transport ability of the resulting doped material. Previously, it was observed that Sn has a high potential for usage as a doping metal for TiO₂ due to the minimal lattice misfit between SnO₂ and TiO₂, which results in strong structural compatibility and stability. In 2014, Thambidurai reported that the PCE of a polymer donor based OSC can be improved (6.70% for TiO₂ and 7.59% for sn-doped TiO₂) by doping its ETL TiO₂ with Sn; this improvement can be attributed to the low shunt loss and interfacial charge recombination provided by the sn-doped TiO₂ ETL based OSC. Recently, Kim et al. reported that the trivalent metal Al doped TiO₂ ETL based OSC can exhibit an enhanced photoactive performance. Owing to the reduced interfacial recombination between the ETL and active layers (due to a highly crystalline upper photoactive layer), reduced trap density in TiO₂ (through the elimination oxygen vacancy by Al), and widening of band gap (by Al doping), the Al doped TiO₂ ETL based OSC exhibits a better PCE value than the undoped TiO₂ based OSC. Other trivalent metals, such as Gallium (Ga) and Indium (In), have recently been used as doping reagents of various metal oxides for ETL applications, but to the best of our knowledge, very few trivalent metals have been evaluated as doping reagents of TiO₂ for ETL applications. Furthermore, the effect of doping metal atomic size on TiO₂ performance has not been investigated. Ga and In are two trivalent metals having different atomic size. Ga atom is significantly smaller than the In and Ti atom.

Therefore, in this study, first we studied the effect of doping by very little amount of Ga and In on the performance of TiO₂ as ETL of Poly [[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]]: Phenyl C71 butyric acid methyl ester (PTB7:PC₇₀BM) active layer based inverted structured OSC. Following that, we investigated whether the atomic size of doping metals affects the performance of TiO₂ as an ETL by comparing the performance of Ga and In doped TiO₂ based OSCs. The test results showed that ETL doping (by trivalent metal) might considerably enhance the PCE of the inverted OSC. Furthermore, despite the fact that the Ga (187 pm) atom is substantially smaller than the In (220 pm) and Ti (215 pm) atoms, the PCE value of the Ga doped TiO₂ ETL based inverted OSC was equivalent to the In doped TiO₂ ETL based one.

### REFERENCE DOCUMENTS

### Non-Patent Documents

[1] K. Fukuda, K. Yu, T. Someya, The future of flexible organic solar cells, Adv. Energy Mater. 10 (2020) 2000765.
[2] Z. Hu, J. Wang, X. Ma, J. Gao, C. Xu, K. Yang, Z. Wang, J. Zhang, F. Zhang, A critical review on semitransparent organic solar cells, Nano Energy 78 (2020), 105376.
[3] M. Riede, D. Spoltore, K. Leo, Organic solar cells—the path to commercial success, Adv. Energy Mater. 11 (2021) 2002653.
[4] Y. Tong, Z. Xiao, X. Du, C. Zuo, Y. Li, M. Lv, Y. Yuan, C. Yi, F. Hao, Y. Hua, Progress of the key materials for organic solar cells, Science China, Chemistry 63 (2020) 758-765.
[5] A. Armin, W. Li, O. J. Sandberg, Z. Xiao, L. Ding, J. Nelson, D. Neher, K. Vandewal, S. Shoaee, T. Wang, A history and perspective of non-fullerene electron acceptors for organic solar cells, Adv. Energy Mater. 11 (2021) 2003570.
[6] L. Duan, A. Uddin, Progress in stability of organic solar cells, Adv. Sci. 7 (2020) 1903259.
[7] F. Zhao, C. Wang, X. Zhan, Morphology control in organic solar cells, Adv. Energy Mater. 8 (2018) 1703147.
[8] A. R. Murad, A. Iraqi, S. B. Aziz, S. N. Abdullah, M. A. Brza, Conducting polymers for optoelectronic devices and organic solar cells: A review, Polymers 12 (2020) 2627.
[9] J. Yuan, H. Zhang, R. Zhang, Y. Wang, J. Hou, M. Leclerc, X. Zhan, F. Huang, F. Gao, Y. Zou, Reducing voltage losses in the A-DA'DA acceptor-based organic solar cells, Chem 6 (2020) 2147-2161.
[10] Y. Wang, J. Lee, X. Hou, C. Labanti, J. Yan, E. Mazzolini, A. Parhar, J. Nelson, J. S. Kim, Z. Li, Recent progress and challenges toward highly stable nonfullerene acceptor-based organic solar cells, Adv. Energy Mater. 11 (2021) 2003002.
[11] P. Bi, X. Hao, Versatile ternary approach for novel organic solar cells: a review, Solar RRL 3 (2019) 1800263.
[12] A. Karki, A. J. Gillett, R. H. Friend, T. Q. Nguyen, The path to 20% power conversion efficiencies in nonfullerene acceptor organic solar cells, Adv. Energy Mater. 11 (2021) 2003441.
[13] S. Biswas, Y.-J. You, J. Kim, S. R. Ha, H. Choi, S.-H. Kwon, K.-K. Kim, J. W. Shim, H. Kim, Decent efficiency improvement of organic photovoltaic cell with low acidic hole transport material by controlling doping concentration, Appl. Surf Sci. 512 (2020), 145700.
[14] S. Biswas, Y.-J. You, Y. Lee, J. W. Shim, H. Kim, Efficiency improvement of indoor organic solar cell by optimization of the doping level of the hole extraction layer, Dyes Pigm. 183 (2020), 108719.
[15] M. A. Saeed, S. Cheng, S. Biswas, S. H. Kim, S.-K. Kwon, H. Kim, Y.-H. Kim, J. W. Shim, Remarkably high performance of organic photovoltaic devices with 3, 9-bis(2-methylene-(3-(1, 1-dicyanomethylene)-indanone))-5, 5, 11, 11-tetrakis (4-hexyl meta-phenyl)-dithieno [2, 3-d: 2′, 3′-d′]-s-indaceno [1,2-b: 5, 6-b′] dithiophene)-ethylhexyloxy] photoactive acceptor under halogen light illumination, J. Power Sources 518 (2022), 230782.
[16] J. Y. Kim, S. Biswas, Y. Lee, H. W. Lee, J. M. Jeon, H. Kim, Highly Efficient Inverted Polymer Solar Cells Using an Indium Gallium Zinc Oxide Interfacial Layer, Solar RRL 5 (2021) 2000673.
[17] Y. Lee, S. Biswas, H. Kim, Effect of hygroscopicity of the hole transport layer on the stability of organic solar cells, Thin Solid Films 139134 (2022).
[18] Z. He, C. Zhong, S. Su, M. Xu, H. Wu, Y. Cao, Enhanced power-conversion efficiency in polymer solar cells using an inverted device structure, Nat. Photonics 6 (2012) 591-595.
[19] Z. A. Tan, W. Zhang, Z. Zhang, D. Qian, Y. Huang, J. Hou, Y. Li, High-performance inverted polymer solar cells with solution-processed titanium chelate as electroncollecting layer on ITO electrode, Adv. Mater. 24 (2012) 1476-1481.
[20] J. Roh, S. Biswas, H. W. Lee, Y. Lee, J. Lee, J. Kim, C. Lee, H. Kim, Top-Gate Field-Effect Transistor as a Testbed for Evaluating the Photostability of Organic Photovoltaic Polymers, Solar RRL.
[21] V.-H. Tran, H. Park, S. H. Eom, S. C. Yoon, S.-H. Lee, Modified SnO₂ with alkali carbonates as robust electron-transport layers for inverted organic solar cells, ACS Omega 3 (2018) 18398-18410.
[22] A. Kyaw, X. Sun, C. Jiang, G. Lo, D. Zhao, D. Kwong, An inverted organic solar cell employing a sol-gel derived ZnO electron selective layer and thermal evaporated MoO 3 hole selective layer, Appl. Phys. Lett. 93 (2008), 221107.
[23] M. K. Al-hashimi, B. Y. Kadem, A. K. Hassan, Rutile TiO₂ films as electron transport layer in inverted organic solar cell, J. Mater. Sci. Mater. Electron. 29 (2018) 7152-7160.
[24] V.-H. Tran, R. B. Ambade, S. B. Ambade, S.-H. Lee, I.-H. Lee, Low-temperature solution-processed SnO₂ nanoparticles as a cathode buffer layer for inverted organic solar cells, ACS Appl. Mater. Interfaces 9 (2017) 1645-1653.
[25] M. Thambidurai, F. Shini, J. Y. Kim, C. Lee, C. Dang, Solution-processed Ga—TiO₂ electron transport layer for efficient inverted organic solar cells, Mater. Lett. 274 (2020), 128003.
[26] M. Thambidurai, J. Y. Kim, H.-J. Song, Y. Ko, N. Muthukumarasamy, D. Velauthapillai, V. W. Bergmann, S. A. Weber, C. Lee, Enhanced power conversion efficiency of inverted organic solar cells by using solution processed Sn-doped TiO₂ as an electron transport layer, J. Mater. Chem. A 2 (2014) 11426-11431.
[27] A. Ranjitha, M. Thambidurai, F. Shini, N. Muthukumarasamy, D. Velauthapillai, Effect of doped TiO₂ film as electron transport layer for inverted organic solar cell, Mater. Sci. Energy Technol. 2 (2019) 385-388.
[28] J. Y. Kim, S. Rhee, H. Lee, K. An, S. Biswas, Y. Lee, J. W. Shim, C. Lee, H. Kim, Universal Elaboration of Al-Doped TiO₂ as an Electron Extraction Layer in Inorganic-Organic Hybrid Perovskite and Organic Solar Cells, Adv. Mater. Interfaces 7 (2020) 1902003.
[29] S. S. Mali, J. V. Patil, H. Kim, C. K. Hong, Gallium cationic incorporated compact TiO₂ as an efficient electron-transporting layer for stable perovskite solar cells, Matter 1 (2019) 452-464.
[30] G. Govindasamy, P. Murugasen, S. Sagadevan, Investigations on the synthesis, optical and electrical properties of TiO₂ thin films by chemical bath deposition (CBD) method, Mater. Res. 19 (2016) 413-419.
[31] F. T. L. Muniz, M. R. Miranda, C. Morilla dos Santos, J. M. Sasaki, The Scherrer equation and the dynamical theory of X-ray diffraction, Acta Crystallographica Section A: Foundations and Advances 72 (2016) 385-390.
[32] G. Jauncey, The scattering of x-rays and Bragg's law, Proceedings of the National Academy of Sciences of the United States of America, 10 (1924) 57.
[33] A. S. Zuruzi, H. C. Gardner, A. J. Monkowski, N. C. MacDonald, Tailored nanostructured titania integrated on titanium micropillars with outstanding wicking properties, Lab Chip 13 (2013) 2414-2418.
[34] Q. Zhang, B. Kan, F. Liu, G. Long, X. Wan, X. Chen, Y. Zuo, W. Ni, H. Zhang, M. Li, Z. Hu, F. Huang, Y. Cao, Z. Liang, M. Zhang, T. P. Russell, Y. Chen, Small-molecule solar cells with efficiency over 9%, Nat. Photonics 9 (2015) 35-41.
[35] D. Chirvase, Z. Chiguvare, M. Knipper, J. Parisi, V. Dyakonov, J. C. Hummelen, Temperature dependent characteristics of poly(3 hexylthiophene)-fullerene based heterojunction organic solar cells, J. Appl. Phys. 93 (2003) 3376-3383.
[36] B. Roose, K. C. G*odel, S. Pathak, A. Sadhanala, J. P. C. Baena, B. D. Wilts, H. J. Snaith, U. Wiesner, M. Gr*atzel, U. Steiner, Enhanced efficiency and stability of perovskite solar cells through Nd-doping of mesostructured TiO₂, Adv. Energy Mater. 6 (2016) 1501868.
[37] J. Peng, T. Duong, X. Zhou, H. Shen, Y. Wu, H. K. Mulmudi, Y. Wan, D. Zhong, J. Li, T. Tsuzuki, Efficient indium-doped TiOx electron transport layers for highperformance perovskite solar cells and perovskite-silicon tandems, Adv. Energy Mater. 7 (2017) 1601768.

### SUMMARY OF THE INVENTION

The technical problem of the present invention is to provide a method for manufacturing an inverted-structure organic solar cell (OSC) with improved power conversion efficiency (PCE) using trivalent metal doping.

To solve the aforementioned problem, the present invention provides an inverted-structure organic solar cell characterized by comprising an electron transport layer (ETL) made of titanium dioxide (TiO₂) doped with a trivalent metal.

Additionally, the present invention provides an inverted-structure organic solar cell characterized in that the trivalent metal is indium (In). Furthermore, the present invention provides an inverted-structure organic solar cell characterized in that the trivalent metal is gallium (Ga). Moreover, the present invention provides an inverted-structure organic solar cell characterized by using PTB7:PC₇₀BM as the active layer.

Additionally, the present invention provides a method for manufacturing an inverted-structure organic solar cell, comprising: A step of preparing a TiO₂ precursor solution using titanium (IV) butoxide (Ti(OCH₂CH₂CH₂CH₂CH₃)₄); A step of dissolving and stirring the TiO₂ precursor solution in a mixture of 2-methoxyethanol (CH₃OCH₂CH₂OH) and acetylacetone (CH₃COCH₂COCH₃); and A step of dissolving Ga(NO₃)₃·xH₂O or In(NO₃)₃·xH₂O in the TiO₂ precursor solution to prepare a doped TiO₂ precursor solution.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a graph showing the XRD profiles of various films formed with TiO₂, In-doped TiO₂, and Ga-doped TiO₂.

FIG. 2 shows SEM images and AFM images of various films formed with TiO₂, In-doped TiO₂, and Ga-doped TiO₂.

FIG. 3 illustrates the device structure of the inverted-structure organic solar cell and the chemical structures of the donor and acceptor materials used in the active layer of the device.

FIG. 4 presents the J-V characteristic curves of various ETL-based OSCs operating under one-sun conditions and the EQE spectra of various ETL-based OSCs.

FIG. 5 is a graph showing the recombination characteristics and activation energy of OSCs based on different ETLs (undoped TiO₂, In-doped TiO₂, and Ga-doped TiO₂).

### DETAILED DESCRIPTION OF EXEMPLARY EMBODIMENTS

The objects and effects of the present invention will become clear through the following detailed description, but are not limited to the following description. In addition, in the description of the present invention, when it is determined that the detailed description of known technologies related to the present invention may unnecessarily obscure the gist of the present invention, the detailed description will be omitted.

Hereinafter, embodiments of the present invention will be described in detail with reference to the attached drawings so that those skilled in the art can easily implement the present invention. However, the present invention may be implemented in various forms and thus is not limited to the embodiments disclosed below. In addition, in order to clearly disclose the present invention in the drawings, parts not related to the present invention are omitted, and identical or similar symbols in the drawings indicate identical or similar components.

Inverted organic solar cells (OSCs) are becoming more popular because to their better durability and photo stability; nonetheless, their power conversion efficiency (PCE) is lower than that of conventional OSCs due to the poor conductivity of the electron transport layer (ETL). Several doped metal oxides have been investigated as possible ETLs to overcome this problem. Various metal doped titanium dioxide (TiO₂) has recently been tested as an ETL for photo- and air-stable OSCs. Due to their physicochemical features, trivalent metals are one of the best possibilities as a TiO₂ doping reagent. Therefore, we investigate at how TiO₂'s performance as an ETL of an inverted OSC may be affected by doping it with a very little quantity of trivalent metal in this study. Additionally, two other metals, such as Indium (In) and Gallium (Ga), are taken into consideration to test the impact of the doping metal's atomic size on TiO₂'s performance as an ETL. The doped-TiO₂ based OSC shows 10.24% higher PCE than undoped-TiO₂ based OSC. Furthermore, despite the fact that Ga's atomic size is substantially smaller than Ti's and In's, both Ga doped-TiO₂ based OSC (7.54%) and In-doped-TiO₂ (7.47%) display almost identical PCE values.

Before examining the inverted-structure organic solar cell utilizing trivalent metal doping according to an embodiment of the present invention with reference to the drawings, the manufacturing method will be described in detail.

### Materials

Titanium (IV) butoxide (Ti(OCH₂CH₂CH₂CH₂CH₃)₄), chlorobenzene (C₆H₅Cl), 1,8-diiodooctane (C₈H₁₆I₂), acetyl acetone (CH₃COCH₂COCH₃), 2-methoxyethanol (CH₃OCH₂CH₂OH), gallium (III) nitrate hydrate (Ga(NO₃)₃·xH₂O), molybdenum trioxide (MoO₃), indium (III) nitrate hydrate (In(NO₃)₃·xH₂O), and anhydrous N,N-dimethylformamide (DMF, 99.8%) were supplied by Sigma-Aldrich. 1-Material, Inc. Ltd. supplied PTB7 and PC₇₀BM. Indium tin oxide (ITO) coated substrates were collected from All for LAB. All of the chemicals were used without additional purification.

### Solution Preparation

The PTB7:PC₇₀BM (1:1.5) solution was prepared in a hybrid solvent of chlorobenzene/1, 8-diiodooctane (97:3 vol %) and stirred at room temperature for whole night in a nitrogen filled glove box.

### Formation of ETL

In this work, the precursor solution for creating TiO₂-based ETL was made using 0.45 M of Ti(OCH₂CH₂CH₂CH₂CH₃)₄, which was mixed in a combination of CH₃OCH₂CH₂OH and 0.45 M of CH₃COCH₂COCH₃. A magnetic stirrer was used to mix the solution for 2 h.

Precursor solutions for Ga- and In-doped TiO₂-based ETL were produced by dissolving Ga(NO₃)₃·xH₂O and In(NO₃)₃·xH₂O in TiO₂ precursor solutions, respectively. During the experiment, the doping ratio was set to 1 at. %.

After that, thin layers of these mixtures were coated onto the pre-cleaned substrates (cleaned using acetone, isopropyl alcohol (IPA), and deionized (DI) water for 10 min each in an ultrasonic bath). The ETLs were formed through calcination at 450° C. for 2 h.

### Measurement Equipment and Conditions

X-ray diffractometer (New D8 Advance) was used to record the XRD patterns of several material-based ETL. The AFM, FESEM, and HRTEM images of different ETLs were captured by XE-100 AFM, Zeiss Supra 55VP SEM, and JEM-3010 TEM respectively. The In and Ga impurity concentration in the TiO₂ films was estimated by a Bruker Energy Dispersive X-ray Spectroscopy (EDX) machine. Keithley 237 source measurement (Newport 91160A) device and a 300 W solar simulator were used to test the J-V characteristics. Lock-in amplifier (Model: 7265, Signal Recovery) was used to measure the wavelength-dependent IPCE of OSCs. We used a SpectroPro-150 (Acton Research Corporation) Xenon lamp with a monochromator for illuminating (monochromatic light). In our study, the OSCs were tested in a vacuum chamber, and the temperature in the chamber was changed using a temperature controller (Lake Shore Cryotronics 331). The measurement started at 100 K and progressed in increments of 25 K until a final value of 350 K was reached. After fixing the temperature, the measurement lasted for 1 h to maintain it.

Hereinafter, the characteristics of the inverted-structure organic solar cell utilizing trivalent metal doping according to an embodiment of the present invention will be examined with reference to the drawings.

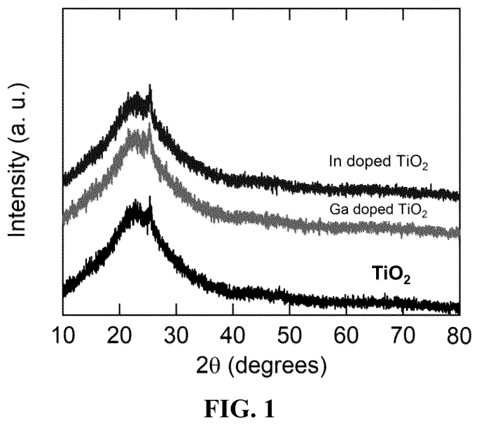

FIG. 1 is a graph illustrating the X-ray diffraction (XRD) profiles of various films formed with TiO₂, In-doped TiO₂, and Ga-doped TiO₂.

After the deposition of different ETLs, we confirmed the formation of TiO₂, and doped TiO₂ with the help of the observation of their X-ray diffraction (XRD) profiles (FIG. 1). The XRD profile of TiO₂ shows a wide diffraction peak at 25.36°, which reflects the (101) planes of TiO₂'s tetragonal wurtzite structure, as seen in FIG. 1. For the In and Ga doped TiO₂, the angle associated with the peak (101) has shifted to 25.37° and 25.50°, respectively. Moreover, from the XRD profiles, we estimated the average grain size (D) of both undoped and doped TiO₂ crystals by employing the Scherrer equation (Eq. (1)),

$$D = \frac{K \times λ}{β cos θ} \qquad ( Eq . 1 )$$

where K, λ, and β is Scherrer constant, wavelength of X-ray, and full width of half maximum of the diffraction angle peak respectively. The value of λ is 1.54 Å for Cu Kα1.

On the other hand, Bragg's law was employed for estimating the lattice spacing, d (Eq. 2),

$$n λ = 2 d sin θ \qquad ( Eq . 2 )$$

where n is integer (+).

From the analysis of XRD profile of different films, the average grain size and ‘d’ of undoped TiO₂ were estimated to be 12.72 nm and 3.42 Å respectively (JCPDS card no. 89-4921); whereas, for In doped TiO₂ film, they were found to be 12.68 nm and 3.28 Å, respectively. The proximity between the D and d values of In doped TiO₂ and undoped TiO₂ films is due to the similar atomic size of In (215 pm) and Ti (220 pm).

On the other hand, the Ga doped TiO₂ exhibited a significant decrement in both the average grain size (11.64 nm) and ‘d’ value (2.14 Å). The atomic size of Ga is 187 pm, which is significantly lower than that of Ti, and owing to this size mismatch, the estimated average grain size and d value of Ga doped TiO₂ are slightly lower than those of undoped TiO₂.

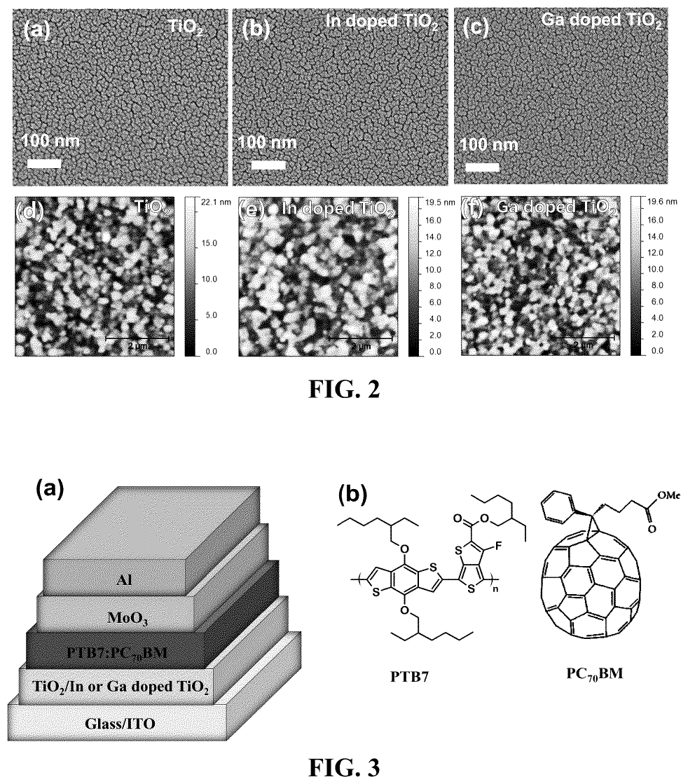

FIG. 2 presents SEM (Scanning Electron Microscopy) and AFM (Atomic Force Microscopy) images of various films formed with TiO₂, In doped TiO₂, and Ga-doped TiO₂.

Scanning electron microscopy (SEM) images of TiO₂, In doped TiO₂, and Ga doped TiO₂ ETLs are shown in (a), (b) and (c) of FIG. 2 respectively. The SEM images of various films show that the grains are spread consistently throughout the surface of the substrate, and all of the films are uniform and crack-free. The findings are supported by AFM images ((d), (e), and (f) of FIG. 2) of those films.

Furthermore, root-mean-square of the surface roughness of an undoped TiO₂ based ETL is 2.91 nm, but it is 2.92 nm and 2.59 nm for In- and Ga doped TiO₂ films, respectively, based on AFM images of the films developed by the various samples. Owing to the proximate average grain sizes of undoped TiO₂ and In doped TiO₂, the film formed by these materials exhibit similar surface roughness. However, the Ga doped TiO₂ has a smaller grain size than the undoped TiO₂, and therefore, its surface roughness value is lower than that of the undoped TiO₂ film. The EDX spectra of In and Ga doped TiO₂ films confirm the presence of the doping elements (In or Ga) within the TiO₂ layer.

Furthermore, elemental analysis shows that 0.76 at. % Ga is present in the Ga doped TiO₂ film, whereas 0.62 at. % In is present in the In doped TiO₂ film. To compare the potentiality of different ETLs for the case of inverted structured OSC, we fabricated different inverted structured OSCs having PTB7:PC₇₀BM active layer with TiO₂, In doped TiO₂, and Ga doped TiO₂ as ETL.

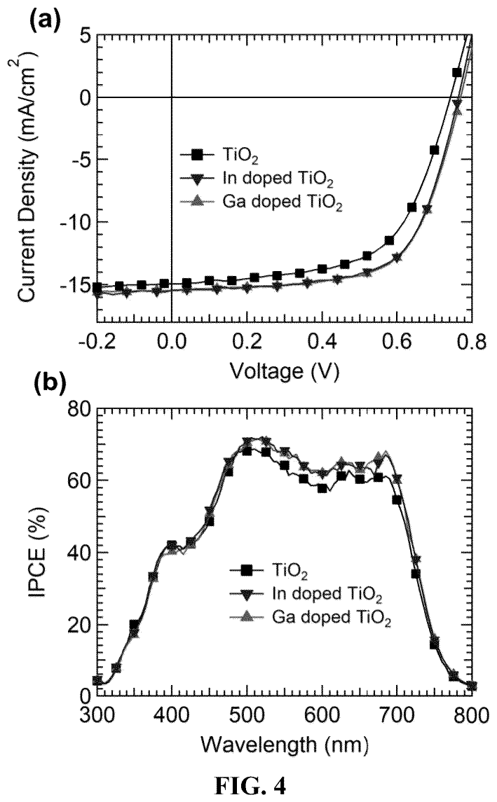

FIG. 3 is a schematic diagram illustrating the device structure of the inverted-structure organic solar cell (OSC) and the chemical structures of the donor and acceptor materials used in the active layer. FIG. 4 presents the J-V characteristic curves of various ETL-based OSCs operating under one-sun conditions and the EQE spectra of various ETL-based OSCs.

Specifically, referring to (a) of FIG. 3, a schematic diagram of an inverse-structure OSC in which doped TiO₂ is used as an electron transport layer (ETL), a PTB7:PC₇₀BM active layer is formed, and molybdenum oxide (MoO₃) is used as a hole extraction layer (HEL) can be confirmed. In addition, referring to (b) of FIG. 3, the chemical structures of PTB7 as a donor of the active layer (PTB7:PC₇₀BM) and PC₇₀BM as an acceptor can be confirmed, respectively.

(a) of FIG. 4 depicts the current density (J)-(V) characteristics of OSCs with ETL formed by TiO₂, In doped TiO₂, and Ga doped TiO₂. The photovoltaic performance parameters (along with standard deviated error) are summarized in Table 1.

TABLE 1
Summary of device performance parameters (averaged for eight devices)
of different ETL-based inverted structured OSCs for 1-sun condition.

| | ETL | | |
|---|---|---|---|
| Parameter | TiO₂ | In TiO₂ | Ga TiO₂ |
| J_{SC} (mA cm⁻²) | 14.80 ± 0.04 | 15.20 ± 0.02 | 15.52 ± 0.03 |
| V_{OC} (V) | 0.75 ± 0.01 | 0.76 ± 0.02 | 0.77 ± 0.06 |
| FF (%) | 61.86 ± 2.1 | 64.56 ± 1.10 | 64.78 ± 0.32 |
| PCE (%) | 6.84 ± 0.09 | 7.47 ± 0.16 | 7.54 ± 0.14 |
| Rₛ (Ωcm²) | 7.61 ± 0.51 | 6.15 ± 0.07 | 6.20 ± 0.11 |
| Rₛₕ (Ωcm²) | 1001.65 ± 5.01 | 1317.80 ± 8.01 | 1302.28 ± 10.01 |

The values of average open circuit voltage (VOC), short circuit current density (JSC), fill factor (FF), and PCE for undoped TiO₂ ETL based OSC is 0.75 V, 14.80 mAcm⁻², 61.86%, and 6.84%, respectively; the values for In doped TiO₂ ETL based OSC are 0.76 V, 15.20 mAcm⁻², 64.50%, and 7.46%, respectively; the values for Ga doped TiO₂ ETL based OSC are 0.77 V, 15.52 mAcm⁻², 64.78%, 7.54%, respectively. Notably, the performance of the inverted structured OSC can be improved significantly by doping its ETL with both In and Ga. Additionally, the performance of Ga doped TIO₂ ETL based one is substantially identical in all aspects to that of In doped TiO₂ ETL based one.

The incident photon to charge carrier efficiency (IPCE) spectra ((b) of FIG. 4) of different ETL based OSCs also exhibits same variation trend. The recombination coefficient (a) of OSC is an important parameter which depends on the light power (PLight) (Eq. (3)),

$${J}_{SC} = {P}_{Light}^{α} \qquad ( Eq . 3 )$$

where α is the recombination coefficient.

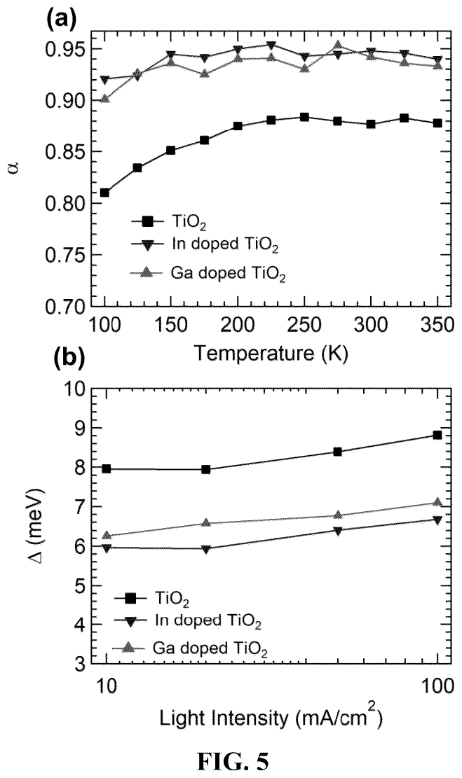

FIG. 5 is a graph illustrating the recombination characteristics and activation energy of organic solar cells (OSCs) based on different electron transport layers (ETLs), including undoped TiO₂, In-doped TiO₂, and Ga-doped TiO₂.

For the estimation of a, we recorded the J-V characteristics curve of the OSCs at various temperatures in the range 100-350 K. (a) of FIG. 5 illustrates the variation of a of different ETL based OSCs with temperature. From (a) of FIG. 5, it is observed that the a of undoped TiO₂ ETL based OSC is approximately 0.8-0.9 within the temperature range, and because of doping of ETL with In or Ga, the value of a of the OSC has increased noticeably (approximately 0.92-1.00). Furthermore, there is no significant variation in the a value when different metals (In, Ga) are used for doping. The doping of the ETL results in an increase in the recombination coefficient of OSC, which indicates an improvement in charge extraction (with less space charge effect) within the device. This outcome is also attributed to the In or Ga-doped TiO₂ layer's improved interfacial energy level alignment, which helps to balance election and hole transport.

Another essential parameter that describes the potential barrier height associated with the charge transport across interlayers is activation energy (A). Smaller A is more favorable for achieving better device performance. It is composed of two parts: the band gap (energy required to excite electrons from HOMO to LUMO) and the energy required to delocalize the charge carriers (i.e. the energy required for an electron to escape from a trap). Phonons can also aid in the delocalization process in organic materials. At low temperatures, the likelihood of finding a phonon with enough energy to permit a hop to the adjacent site is minimal. Charge carrier mobility, and so conductivity, should increase as temperature rises. As a general conclusion for organic materials, at low temperatures, few charge carriers are thermally produced and are not easily transferred; hence, the current is minimal in the absence of light.

The value of Δ can be calculated using temperature dependent JSC data at different light intensity. The J-V curves of TiO₂, In doped TiO₂, and Ga doped TiO₂ ETLs based OSCs at temperatures ranging from 100 to 350 K and light intensities ranging from 10 to 100 mWcm⁻², shows that the device performance of doped TiO₂ ETL-based OSC is superior to that of undoped TiO₂ based devices. The JSC of OSCs grew linearly as temperature increased, whereas VOC rose as temperature decreased since VOC is inversely related to temperature. The Δ value is estimated using Eq. (4) and the results of the J-V characteristics at different temperature and light intensities:

$${J}_{SC} ( T , {P}_{Light} ) = {J}_{0} ( {P}_{Light} ) exp ( \frac{Δ}{{K}_{B} \times T} ) \qquad ( Eq . 4 )$$

(b) of FIG. 5 illustrates the variation of Δ of OSCs having different ETLs with light intensity. In (b) of FIG. 5, it is interesting to observe that the Δ value in doped ETL (In or Ga doped TiO₂) based OSCs is lower than that of undoped ETL (TiO₂) based OSC. This suggests that the OSC's ETL can be doped with a trivalent metal to minimize the potential barrier between its interlayers, and as a result, the OSC with the doped TiO₂ based ETL can perform better than the undoped TiO₂ based one. Furthermore, the effect of atomic size of the doping metal on the decrement in the potential barrier is negligible. Because of this, it's likely that the Ga doped TiO₂ based OSC performed similarly to the In doped TiO₂ ETL based OSC (Table 1) although having much lower atomic sizes (Ga (187 pm) compared to Ti (215 pm) and In (220 pm), respectively). All of the foregoing data indicate that doping TiO₂ with trivalent metal can greatly increase its performance as an ETL, but there is no significant effect of doping metal on its performance as an ETL.

In conclusion, we investigated the influence of small amounts of trivalent metal doping on the potential of TiO₂ as the ETL of a PTB7:PC₇₀BM active layer-based inverted structured OSC. It was observed that the undoped TiO₂ based OSC showed 6.84% PCE; whereas the Ga doped TiO₂ based OSC showed 7.54% PCE, which similar to the PCE value exhibited by the In doped TiO₂ based OSC (7.47%). Doping with trivalent metals In or Ga lowered the density of electron trap state to the TiO₂ lattice by eliminating oxygen vacancies. This improved TiO₂'s electron extractability, and as a result, the doped TiO₂ ETL-based OSCs had a much higher PCE value than the undoped TiO₂-based OSCs. However, despite the fact that the atomic size of Ga is significantly smaller than that of In and Ti, no significant effect of doping metal atomic size on the performance of TiO₂ as ETL was observed because this phenomenon has no effect on the charge transport characteristic (recombination coefficient, activation energy, etc.) of the entire system.

According to the present invention, it is possible to manufacture an inverted-structure OSC with improved PCE compared to conventional inverted-structure OSCs.

The preferred embodiments of the present invention described above are disclosed for illustrative purposes, and those skilled in the art will be able to make various modifications, changes and additions within the spirit and the scope of the present invention, which should be considered as falling within the scope of the patent claims. In addition, since those skilled in the art to which the present invention pertains can make various substitutions, modifications and changes without departing from the technical spirit of the present invention, the present invention is not limited to the above-described embodiments and attached drawings.

In the above-described exemplary system, the methods are described on the basis of a flowchart as a series of steps or blocks, but the present invention is not limited to the order of the steps, and some steps may occur in a different order or may occur simultaneously as described above. In addition, those skilled in the art will understand that the steps described in the flowchart are not exclusive and that other steps may be included or one or more steps in the flowchart may be deleted without affecting the scope of the present invention.

What is claimed is:

1. An inverted-structure organic solar cell (OSC) comprising an electron transport layer (ETL) made of trivalent metal-doped titanium dioxide (TiO₂).

2. The inverted-structure organic solar cell of claim 1, wherein the trivalent metal is indium (In).

3. The inverted-structure organic solar cell of claim 1, wherein the trivalent metal is gallium (Ga).

4. The inverted-structure organic solar cell of claim 1, wherein the active layer comprises PTB7:PC₇₀BM.

5. The inverted-structure organic solar cell of claim 1, wherein the hole extraction layer (HEL) comprises molybdenum trioxide (MoO₃).

6. A method for manufacturing an inverted-structure organic solar cell, comprising:
preparing a TiO₂ precursor solution using titanium (IV) butoxide (Ti(OCH₂CH₂CH₂CH₂CH₃)₄);
dissolving and stirring the TiO₂ precursor solution in a mixture of 2-methoxyethanol (CH₃OCH₂CH₂OH) and acetylacetone (CH₃COCH₂COCH₃); and
dissolving Ga(NO₃)₃·xH₂O or In(NO₃)₃·xH₂O in the TiO₂ precursor solution to prepare a doped TiO₂ precursor solution.

7. The method for manufacturing an inverted-structure organic solar cell of claim 6, wherein the doping ratio of Ga(NO₃)₃·xH₂O or In(NO₃)₃·xH₂O is 1 at. %.

8. The method for manufacturing an inverted-structure organic solar cell of claim 6,
wherein the TiO₂ precursor solution is dissolved and stirred in a mixture of 2-methoxyethanol (CH₃OCH₂CH₂OH) and acetylacetone (CH₃COCH₂COCH₃) for 2 hours using a magnetic stirrer; and
wherein the TiO₂ precursor solution is calcined at 450° C. for 2 hours to fabricate an electron transport layer (ETL) made of titanium dioxide (TiO₂).
